(19) United States
(12) Patent Application Publication
(10) Pub. No.: US 2012/0250274 A1
(43) Pub. Date: Oct. 4, 2012

(54) Wiring Substrate and Electronic Device

(76) Inventors: Yasunari Ukita, Ome-shi (JP); Kiyokazu Ishizaki, Akishima-shi (JP); Naonori Watanabe, Ome-shi (JP); Tomonori Kawata, Ome-shi (JP); Terunari Kanou, Hamura-shi (JP)

(21) Appl. No.: 13/274,990

(22) Filed: Oct. 17, 2011

(30) Foreign Application Priority Data
Mar. 31, 2011 (JP) 2011-080236

(51) Int. Cl. H05K 5/00; H05K 1/16; H05K 1/11

(52) U.S. Cl. 361/752; 174/266; 174/260

(57) ABSTRACT

In one embodiment, there is provided a wiring substrate. The wiring substrate includes: a substrate body comprising a first surface and a second surface opposite to the first surface, wherein the substrate body has a plurality of first through holes; a plurality of first pads on the first surface of the substrate body; a plurality of second pads on the first surface of the substrate body, wherein the second pads are surrounded by the first pads. Each of the second pads has at least one second through hole, and the second pads are disposed on the first surface of the substrate body such that each of the second through holes is communicated with a corresponding one of the first through holes.

### CROSS-REFERENCE TO RELATED APPLICATION

This application claims priority from Japanese Patent Application No. 2011-080236 filed on Mar. 31, 2011, the entire contents of which are hereby incorporated by reference.

### BACKGROUND

1. Field

Embodiments described herein relate to a wiring substrate and an electronic device including the wiring substrate.

2. Description of Related Art

In recent years, a central processing unit (CPU) used in an information processor such as a computer has achieved a high degree of performance, and as a result, a caloric value has also increased rapidly. As a method for cooling a heat generating component such as the CPU, a technology has been known that cools the heat generating component by contacting a heat dissipating member having a heat dissipating fin with the heat generating component. Meanwhile, a method has been conceived for dissipating heat by conducting the heat to the surface, the inside or a rear surface of a substrate on which the heat generating component is mounted.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention:

FIG. 1 is a perspective view illustrating an electronic device according to an exemplary embodiment;

FIG. 2 is a cross-sectional view illustrating a semiconductor component according to the exemplary embodiment;

FIG. 3 is a plan view illustrating a component viewed from a substrate-side;

FIG. 4 is a partial cross-sectional view illustrating a substrate according to the exemplary embodiment;

FIG. 5 is a plan view illustrating a substrate viewed from a component-side surface opposing the substrate;

FIG. 6 is a partial cross-sectional view illustrating a substrate assembly according to an exemplary embodiment.

FIG. 7 is a diagram showing an example illustrating the shape of a second pad;

FIG. 8 is a diagram showing another example illustrating the shape of a second pad;

FIG. 9 is a diagram showing another example illustrating the shape of a second pad;

FIG. 10 is a diagram showing another example illustrating the shape of a second pad;

FIG. 11 is a diagram showing another example illustrating the shape of a second pad; and

FIGS. 12A to 12F are explanatory diagrams illustrating a manufacturing process of the substrate assembly.

### DETAILED DESCRIPTION

According to exemplary embodiments of the present invention, there is provided a wiring substrate. The wiring substrate includes: a substrate body comprising a first surface and a second surface opposite to the first surface, wherein the substrate body has a plurality of first through holes; a plurality of first pads on the first surface of the substrate body; a plurality of second pads on the first surface of the substrate body, wherein the second pads are surrounded by the first pads. Each of the second pads has at least one second through hole, and the second pads are disposed on the first surface of the substrate body such that each of the second through holes is communicated with a corresponding one of the first through holes.

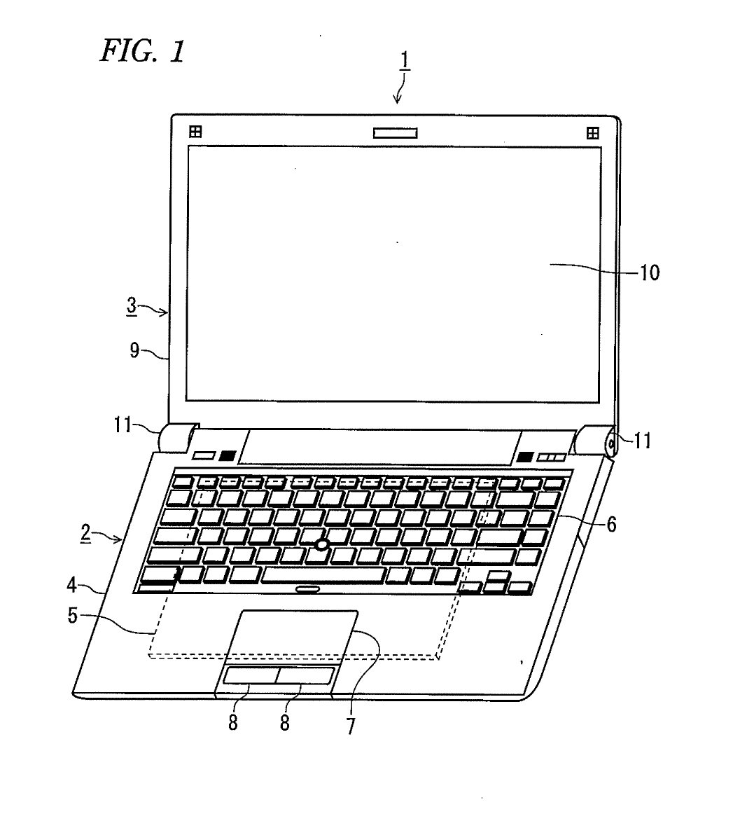

Hereinafter, exemplary embodiments will be described with reference to the accompanying drawings. FIG. 1 is a generalized perspective view showing a personal computer 1 (hereinafter, referred to as a PC) which is one example of an electronic device according to an exemplary embodiment. Further, the electronic device may be mounted with a small-sized thin substrate assembly, such as portable terminals including a cellular phone, a PDA, information recording apparatuses including a hard disk drive (HDD), a solid state drive (SSD), an optical disk drive (ODD), a game instrument, video and audio instruments such as a television in addition to PC.

PC 1 includes a body unit 2 and a display unit 3. The body unit 2 includes, for example, a lower case 4 made of a synthetic resin in a box shape, a substrate assembly 5 disposed in the lower case 4, an information recording device such as a HDD or an SSD (not shown), and a battery, or the like. A keyboard 6, a touch pad 7, and a button 8 are installed on a top surface of the lower case 4. A CPU, a read only memory (ROM), a random access memory (RAM), a flash memory, and other semiconductor components are mounted on the substrate assembly 5.

The display unit 3 includes, for example, an upper case 9 made of the synthetic resin and a display 10 disposed in the upper case 9, or the like. The upper case 9 is formed to surround the circumference of the display 10. The display 10 is, for example, a liquid crystal display. A hinge portion 11 is provided between the lower case 4 and the upper case 9, rotatably supporting the upper case 9 with respect to the lower case 4.

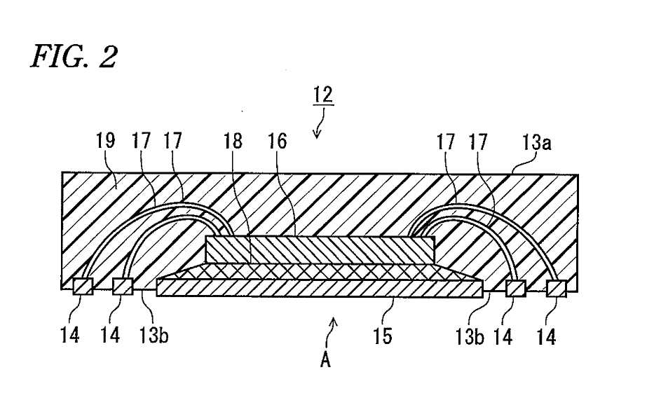

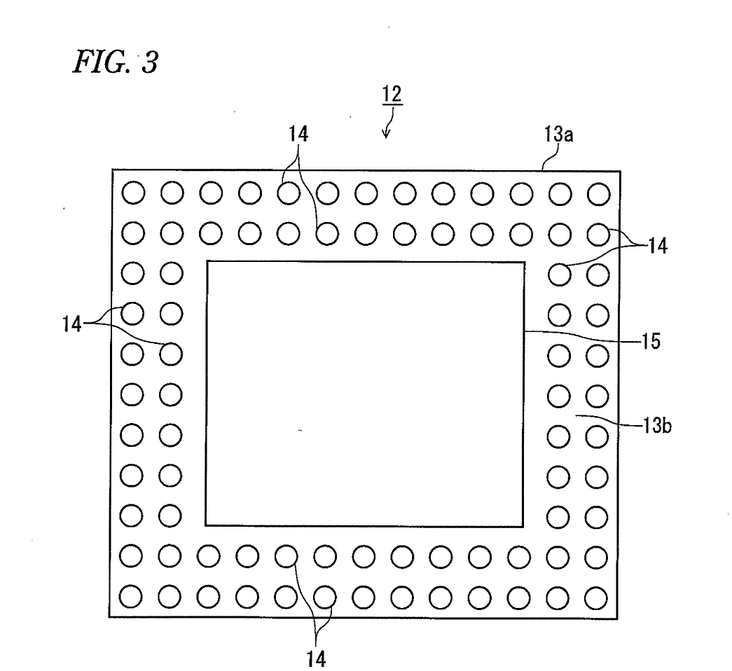

FIG. 2 is a cross-sectional view illustrating a component 12 according to an exemplary embodiment. The component 12 is, for example, a semiconductor component of a land grid array (LGA) provided with a heat dissipating pad called a lead less chip carrier (LLCC) or a quad flat no lead package (QFN). FIG. 3 is a plan view illustrating the component 12 viewed from a substrate-side (arrow A in FIG. 2) mounted with the component 12.

On a surface 13b of a package 13a of the component 12, electrodes 14, 15 are disposed and serve as a first electrode and a second electrode, respectively. The electrode 15 is positioned substantially at the center of the surface 13b and is formed in a rectangular shape. The electrode 15 serves as a heat dissipating electrode that dissipates heat to the outside from the inside of the component 12. Further, the electrode 15 may serve as a ground electrode. In addition, there may be the case where the electrode 15 is not used as the ground electrode.

Electrodes 14 are provided in a rectangular annular region between a rectangular side of the electrode 15 and an outer peripheral side of the surface 13b. Further, the electrodes 14 are provided to surround the electrode 15. The electrodes 14 may serve as signal electrodes. In addition, some of the electrodes 14 may not be used as the signal electrode.

In the package 13a of the component 12, a chip 16 is disposed substantially at the center, and plural signal pads (not shown) on the chip 16 and the electrodes 14 are connected with each other by a bonding wire 17. The chip 16 is mounted on the electrode 15 through a bonding material 18, and the bonding material 18 conducts heat of the chip 16 to the electrode 15. The chip 16 and the bonding wire 17 are sealed by a sealing member 19 such as an underfill agent or a molding agent including a synthetic resin.

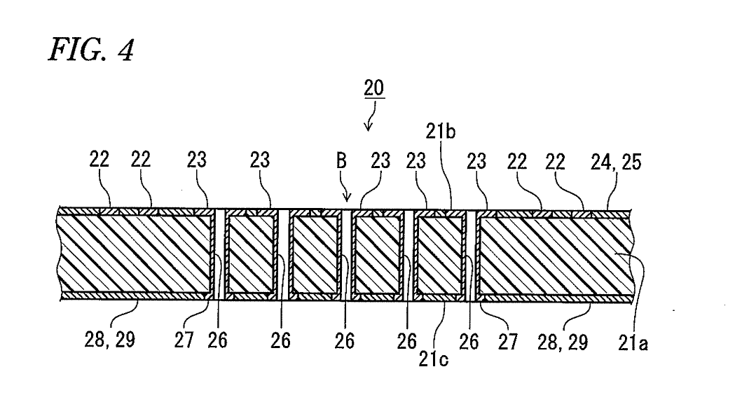

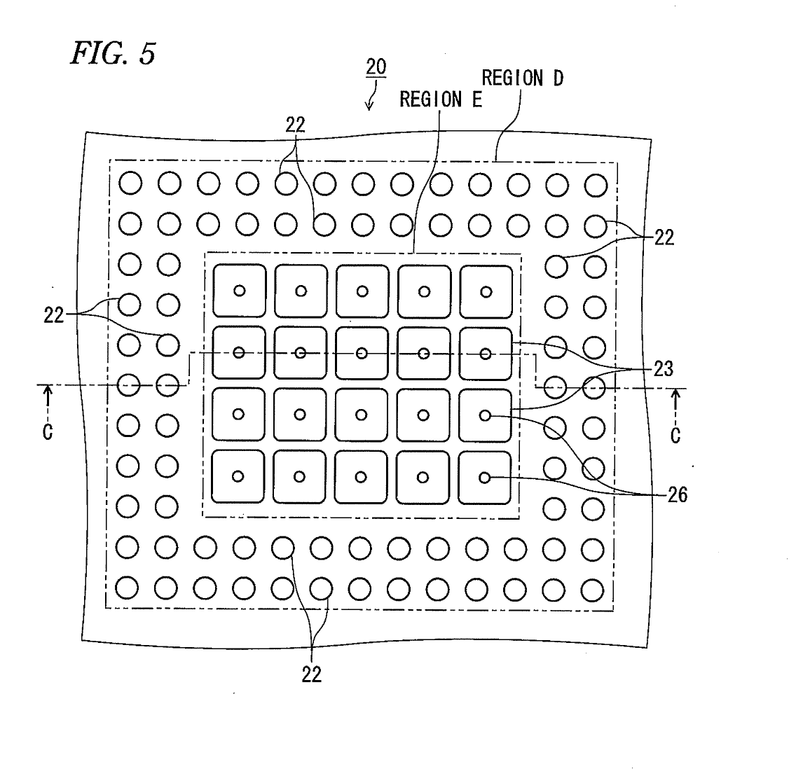

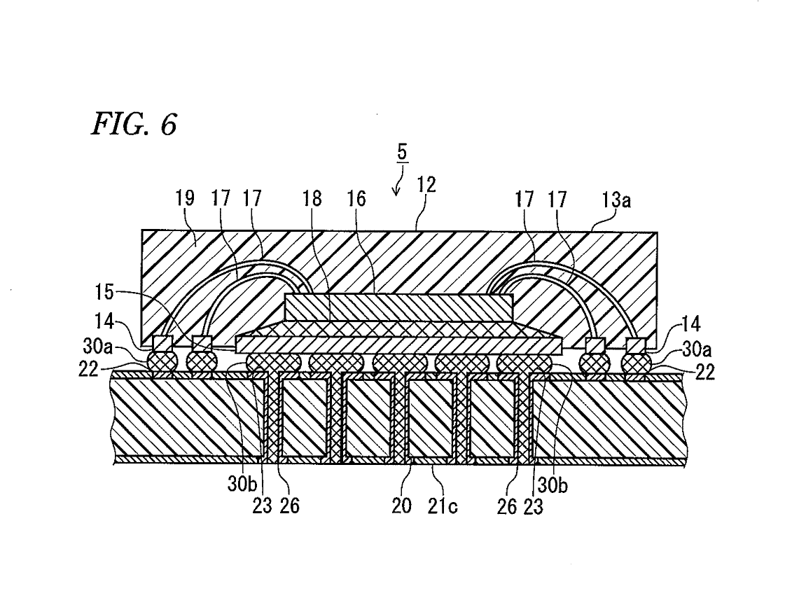

FIG. 4 is a partial cross-sectional view illustrating a substrate 20 according to the exemplary embodiment. The substrate 20 may be a printed circuit substrate. FIG. 5 is a plan view of the substrate 20 viewed from a side where the component 12 is mounted (arrow B shown in FIG. 4). FIG. 4 is a cross section taken along C-C line of FIG. 5. In FIG. 5, a region D indicated by the chain double dashed line represents an outer shape of the package 13a of the component 12 where the component 12 is mounted (see FIG. 6). Further, region E indicated by the chain double dashed line represents an outer shape of the electrode 15 of the component 12 where the component 12 is mounted (see FIG. 6).

In the substrate 20, pads 22 serving as first pads and pads 23 serving as second pads are disposed on a surface 21b where the component 12 is mounted. A solder resist 25 is formed in a region 24 other than regions where the pads 22, 23 are formed.

The pads 23 are formed at a position opposite to the electrode 15 serving as the second electrode of the component 12. As shown in FIG. 5, the region E opposed to the electrode 15 is divided into plural areas, where the plural pads 23 are disposed in a lattice pattern. Each of the pads 23 is formed in a substantially rectangular shape and is separated from each other. Also, each of the pads 23 has a through hole 26 therethrough substantially at the center thereof.

Each of the pads 23 has substantially the same shape, and also has substantially the same area size. The through holes 26 is disposed substantially at the center of the pads 23, and formed in a substantially circular. The diameter of each of the through holes 26 is substantially the same. The pads 23 are electrically connected to pads 27 provided on a rear surface 21c of the substrate 20 through inner walls of the through holes 26. A solder resist 29 is formed in a region 28 other than regions where the pads 27 or other pads are formed. Further, the shape of the pads 27 is not limited to a rectangular shape.

The pads 22 are formed at a position opposite to the electrodes 14 serving as the first electrode of the component 12. As shown in FIG. 5, the pads 22 are disposed to surround the pads 23. In FIG. 5, the shape of the pads 22 is not limited to the circular shape.

FIG. 6 is a partial cross-sectional view illustrating the substrate assembly 5 according to the exemplary embodiment. In the substrate assembly 5, the component 12 is bonded onto the surface 21b of the substrate 20 by bonding materials 30a, 30b such as a solder. The bonding materials 30a, 30b are made of the same material, and a conductive adhesive may be used as the bonding materials 30a, 30b instead of the solder.

Each of the electrodes 14 is bonded to a corresponding one of the pads 22 through the bonding material 30a. The electrode 15 is bonded to each of the pads 23 through the bonding material 30a.

The bonding material 30b flows in the through holes 26 in a reflow process and extends to the rear surface 21c of the substrate 20. With this configuration, the heat of the chip 16 conducted to the bonding material 30b is dissipated from the rear surface 21c, and therefore the heat of the component 12 can be efficiently dissipated. Further, in a case where the substrate 20 is a multi-layered substrate, heat is easily conducted to copper in inner layers of the substrate to be efficiently dissipated in a substrate thickness direction.

In general, as the volume of the bonding materials bonded to the electrode 15 increases, it is difficult to form a void. As shown in FIG. 6, the bonding material bonded to the electrode 15 may be divided into plural bonding materials 30b so as to reduce the void of the bonding materials. The air in a space between the divided bonding materials 30b or the void discharged from the bonding materials 30b is discharged toward outside of the region E of the pads 23 through the space between the bonding materials 30h.

The voids generated within the bonding materials 30b flows into the through holes 26 while some of the bonding materials 30b flow into the through holes 26, and then are discharged from the rear surface 21c. As a result, it is possible to suppress the voids from being remained within the bonding materials 30b.

As the volume of the bonding materials bonded to the electrode 15 increases, the component 12 tends to be easily deviated or inclined by the influence of a deviation caused by the condensation of the bonding materials. For this reason, the bonding materials are divided as described above. As shown in FIG. 6, the bonding materials bonded to the electrode 15 may be divided into plural bonding materials 30b to reduce the influence of a deviation caused by the condensation of the bonding materials, thereby preventing the component 12 from being deviated or inclined. In case of dividing the bonding materials 30b, the shapes of the plural pads 23 may be substantially the same, and also the area sizes of plural pads 23 may be substantially the same. Therefore, the volumes of the bonding materials 30b may become the same as each other and an overall deviation caused by the condensation among the divided bonding materials 30b may be reduced.

A bonding area of the electrode 15 and the bonding materials 30b may be increased so that heat of the chip 16 can be conducted to the bonding materials 30b. A heat dissipating pad of LLCC or QFN is formed in a rectangular shape in most cases, and thus the electrode 15a is formed in a rectangular shape (see FIG. 3). In order to make the divided pads having substantially the same shape and area and increase the bonding area of the electrode 15, the shape of the pads 23 may be substantially rectangular.

For example, when the pads 23 are formed in a circular shape, a gap is formed between the adjacent pads 23. Also, when the pads 23 are formed in a triangular shape or a hexagonal shape, a gap is formed between the adjacent electrode 15. Therefore, when the shape of the electrode 15 is a rectangular shape, the shape of the pads 23 is also a rectangular to increase the bonding area. The divided number of the pads 23 may be appropriately determined depending on the size of the electrode 15, the size of the pads 23, and the size of the through holes 26.

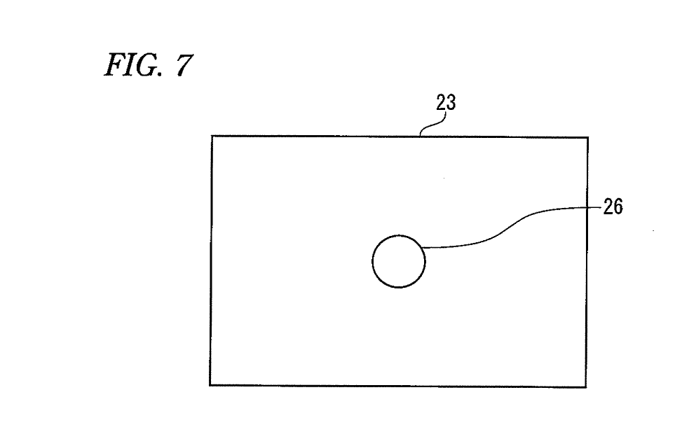

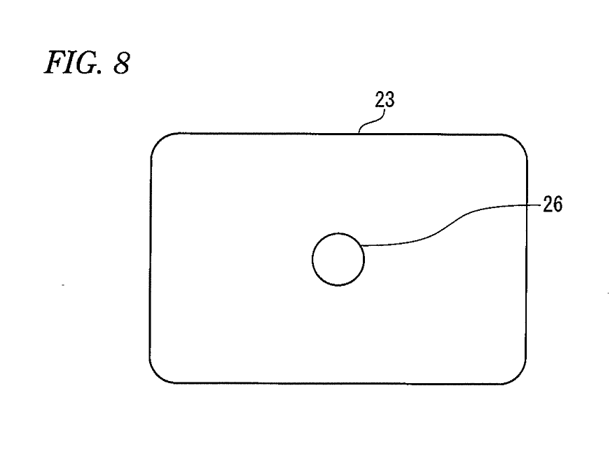

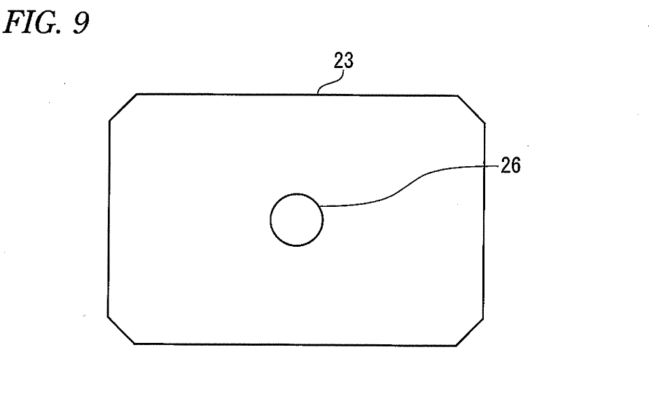

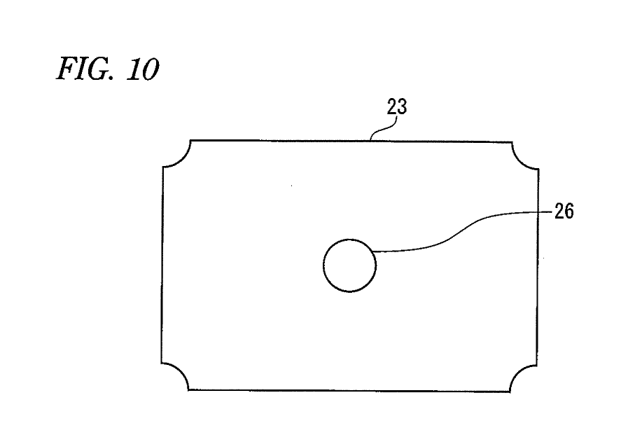

FIGS. 7 to 10 are diagrams showing an example illustrating the shapes of pads 23 (second pad). FIG. 7 shows the pad 23 having rectangular shape. The through hole 26 is formed substantially at the center of the pad 23. FIG. 8 shows the pad 23 whose four corner portions are rounded. FIG. 9 shows the pad 23 whose four corner portions are chamfered. FIG. 10 shows the pad 23 whose four corner portions have rounded shape toward the inside of the rectangle.

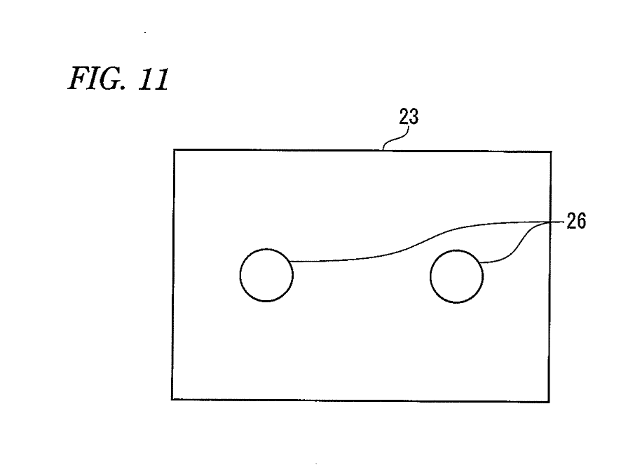

FIG. 11 shows the pad 23 which is formed in a rectangular shape and has two through holes 26 therethrough. By providing the plural through holes 26 in one pad 23, it is possible to improve the heat dissipating efficiency or suppress the void from being remained in the bonding materials 30b. When the plural through holes 26 are formed in the pad 23, the amount of the bonding materials 30b filled in the through holes 26 increases. Therefore, it is possible to adjust the amount of the bonding materials 30b.

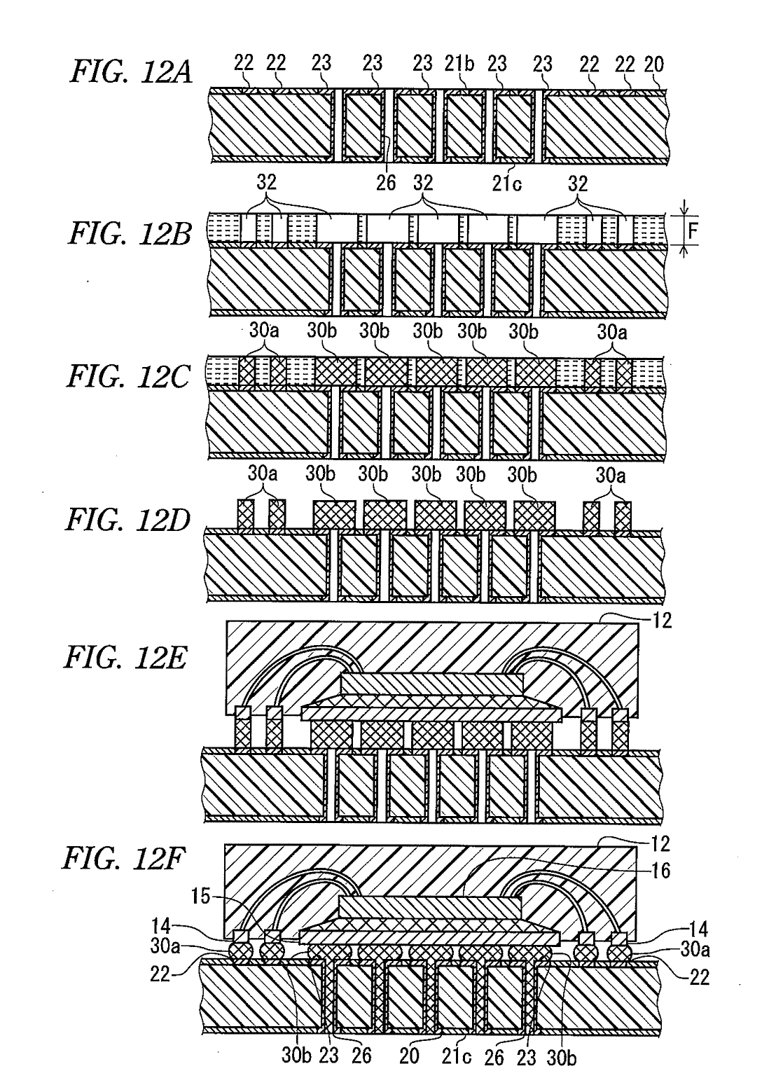

FIGS. 12A to 12F are explanatory diagrams illustrating a manufacturing process of the substrate assembly 5. A method of bonding the component 12 to the substrate 20 through a reflow method will be now described. As shown in FIG. 12A, the pads 22 and 23 corresponding to the electrodes 14 and 15 of the component 12 are formed on a surface 21b of the substrate 20. Then, the substrate 20 is set in a given position.

Subsequently, as shown in FIG. 12B, a mask 31 having through holes 32 is arranged on the surface 21b of the substrate 20. The mask 31 is formed in a planar shape and has a given thickness F. The mask 31 is set such that the respective through holes 32 are arranged on the pads 22, 23 of the substrate 20.

Next, as shown in FIG. 12C, the bonding materials 30a and 30b having a certain liquidity are filled in the through holes 32. In this case, the bonding materials 30a, 30b are filled in the plural through holes 32 such that the heights of the bonding materials 30a, 30b are constant, and the thicknesses of the bonding materials 30a, 30b are the same as thickness F of the mask 31. As the bonding materials 30a, 30b, for example, a solder paste may be used.

Next, as shown in FIG. 12D, the mask 31 is removed and the bonding materials 30a, 30b are remained on the pads 22, 23. Thus, the bonding materials 30a, 30b are formed on the pads 22, 23.

Next, as shown in FIG. 12E, the component 12 is provided on the substrate 20 at a predetermined position. In this process, for example, a numerical control chip mounter (a surface mounter or a component mounter) may be used.

Next, as shown in FIG. 12F, a reflow process is performed while the component 12 is disposed on the substrate 20. According to the reflow process, the substrate 20 mounted with the component 12 is heated, for example, in a reflow furnace. Though this reflow process, the bonding materials 30b are filled in through holes 26. Thereafter, the substrate 20 is cooled, thereby obtaining the substrate assembly 5.

As described above, the region E of the substrate 20 is divided into plural regions, and the respective pads 23 are disposed on the corresponding area divided in a lattice pattern. Each of the pads 23 is formed in substantially rectangular shape and separated from each other, and the through holes 26 are formed in the pads 23. With this configuration, the bonding materials 30b flow into the respective through holes 26 through the reflow process, and extend to the rear surface 21c of the substrate 20. Thus, the heat of the chip 16 conducted to the bonding materials 30b may also be dissipated from the rear surface 21c, thereby dissipating the heat of the component 12 efficiently.

Further, the bonding materials bonded to the electrode 15 may be divided into the plural bonding materials 30b to suppress the formation of the void in the bonding materials. In addition, the areas of the pads 23 may be substantially the same, so that the volumes of the bonding materials 30b are constant and the deviation of the condensation between the divided bonding materials 30b can be reduced. Thus, it is possible to prevent the component 12 from being deviated or inclined. As a result, the component 12 may be bonded onto the substrate 20 in an excellent condition.

While certain embodiments have been described, these embodiments have been presented by way of example only, and are not intended to limit the scope of the invention. Indeed, the novel methods and systems described herein may be embodied in a variety of other forms. Furthermore, various omissions, substitutions and changes in the form of the methods and systems described herein may be made without departing from the sprit of the invention. The accompanying claims and their equivalents are intended to cover such forms or modifications as would fall within the scope and sprit of the invention.

What is claimed is:

1. A wiring substrate, comprising:
a substrate body comprising a first surface and a second surface opposite to the first surface, wherein the substrate body has a plurality of first through holes;
a plurality of first pads on the first surface of the substrate body;
a plurality of second pads on the first surface of the substrate body, wherein the second pads are surrounded by the first pads;
wherein each of the second pads has at least one second through hole, and the second pads are disposed on the first surface of the substrate body such that each of the second through holes is communicated with a corresponding one of the first through holes.

2. The wiring substrate of claim 1, wherein each of the second pads has a single second through hole which is formed in a substantially center of the second pad.

3. The wiring substrate of claim 1, wherein each of the second pads has a plurality of second through holes.

4. The wiring substrate of claim 1, wherein the second pads are disposed on the first surface of the substrate body to be separated from each other.

5. An electronic device comprising:
a wiring substrate, comprising:
a substrate body comprising a first surface and a second surface opposite to the first surface, wherein the substrate body has a plurality of first through holes;
a plurality of first pads on the first surface of the substrate body;
a plurality of second pads on the first surface of the substrate body, wherein the second pads are surrounded by the first pads;
wherein each of the second pads has at least one second through hole, and
the second pads are disposed on the first surface of the substrate body such that each of the second through holes is communicated with a corresponding one of the first through holes;
an electronic component disposed on the wiring substrate and comprising:
a plurality of first electrodes electrically connected to the first pads via first bonding materials; and
a plurality of second electrodes electrically connected to the second pads via second bonding materials, and
wherein the second bonding materials are disposed between the second electrodes and the second pads while the respective first through holes are filled with the second bonding materials.

6. The electronic device of claim 5, further comprising:
a housing which houses the wiring substrate and the electronic component.
